(19) United States
(12) Patent Application Publication
(10) Pub. No.: US 2021/0055150 A1
(43) Pub. Date: Feb. 25, 2021

(54) CAPACITIVE LEVEL SENSOR HAVING AUTOCALIBRATION FACILITY

(71) Applicant: BILLI AUSTRALIA PTY LTD, Thomastown, Victoria (AU)

(72) Inventor: LYNTON MCKAY, THOMASTOWN , VICTORIA (AU)

(21) Appl. No.: 16/958,288

(22) PCT Filed: Dec. 21, 2018
(86) PCT No.: PCT/AU2018/051402

§ 371 Date: Jun. 26, 2020

(30) Foreign Application Priority Data
Dec. 28, 2017 (AU) 2017905208

(51) Int. Cl. G01F 23/26

(52) U.S. Cl. CPC G01F 23/265; G01F 23/266

(57) ABSTRACT

An electronic sensor capable of determining the level of a flowable substance, such as liquid (including water). Such a sensor an elongate probe fixed within or proximal to a body of the flowable substance and are adapted to output an electrical signal or data that is used to estimate the level of the flowable substance around or proximal to the probe. In one form, the sensor includes a capacitive level sensor probe generally elongate and including conductors configured such that, in use, as the level of a flowable substance crosses a first predetermined point along the length of the sensor a first detectable alteration in capacitance is generated, and as the level of a flowable substance crosses a second predetermined point along the length of the sensor a second detectable alteration in capacitance is generated. A probe of this arrangement is amenable to use in an autocalibration method.

### FIELD OF THE INVENTION

The present invention relates generally to the field of electronic sensors capable of determining the level of a flowable substance. Such sensors typically comprise an elongate probe which is fixed within or proximal to a body of the flowable substance and are adapted to output an electrical signal or data that is used to estimate the level of the flowable substance around or proximal to the probe.

### BACKGROUND TO THE INVENTION

In many applications, it is important or at least desirable to establish the level of a flowable substance within a vessel or container. For example it is desirable to know the level of a liquid or a vapour within a tank, or a grain within a silo. A vessel may be required to have a minimum amount of water contained therein or to have no more than a maximum amount, in which case a. In some cases, the level may be considered as a proportion of the total vessel capacity (for example 25%, or 75%), this giving the user an indication of any need to manually replenish the vessel.

In some situations, the output of a level sensor is machine readable and used by an electric or electronic control system whereby the level of liquid in a vessel as reported by the sensor is used to actuate valves, pumps, heater, diverters and the like.

Level sensor devices generally fall into one of two categories. An older type of sensor relies upon fluid mechanics, and includes a pivot arm having a float connected to the distal end which is buoyed on the surface of a liquid. The angle formed by the pivot arm to the horizontal provides an indication of the liquid level. A more advanced type of level sensor relies upon an electrical property of the flowable substance under measurement to generate signals in an electronic circuit, which in turn, provides an indication of the level of the flowable substance.

With regard to electric and electronic liquid level sensors, a preferred electrical property for sensing the level is the dielectric property of the flowable substance as compared to that of the air space above the substance. In order to sense the dielectric property, a capacitive sensor is used, wherein the electrical field between two electrical conductors of the sensor is affected by the presence of the flowable substance. As the level of flowable substance rises during filling, air (which has a low dielectric constant) is replaced with the flowable substance which has a higher dielectric constant. Overall, the capacitive value read from the sensor climbs as the level of flowable substances rises about the sensor.

While of clear utility, prior art capacitive level sensor probes can be of complex construction and therefore expensive to fabricate. For example, some sensors are constructed from concentric metal cylinders, one disposed internal to the other. The cylinders must be held in precise spaced arrangement so as to ensure reproducible capacitance readings. Deformation of one of the cylinders can alter the spaced arrangement leading to undesirable alterations in capacitive output.

Furthermore, capacitive level sensors typically require an initial calibration process and often recalibration at intervals so as to provide a true indication of fill level. This process may be carried out imprecisely by an end user, or may need to be performed by a properly trained technician. In any event, a capacitive level sensor is typically calibrated only for a certain substance. The capacitance measured by a sensor is dependent on the dielectric constant of substance under measurement, and so manual recalibration is required for a substance having a different dielectric constant to that used to conduct any calibration.

It is an aspect of the present invention to overcome or alleviate a problem of the prior art by providing a level sensor that is of simple construction, and/or capable of simple calibration, and/or self-calibration.

The discussion of documents, acts, materials, devices, articles and the like is included in this specification solely for the purpose of providing a context for the present invention. It is not suggested or represented that any or all of these matters formed part of the prior art base or were common general knowledge in the field relevant to the present invention as it existed before the priority date of each claim of this application.

### SUMMARY OF THE INVENTION

In a first aspect, but not necessarily the broadest aspect, the present invention provides a capacitive level sensor probe being generally elongate and comprising conductors configured such that, in use, as the level of a flowable substance crosses a first predetermined point along the length of the sensor a first detectable alteration in capacitance is generated, and as the level of a flowable substance crosses a second predetermined point along the length of the sensor a second detectable alteration in capacitance is generated.

In one embodiment of the first aspect, the detectable alteration in capacitance is an alteration in the rate of change of capacitance, or a transition between two capacitance values, or a brief excursion from a capacitance value.

In one embodiment of the first aspect, the capacitive level sensor probe comprises a first conductor and a second conductor, the first conductor extending along the probe for a first distance, the second conductor extending along the probe for a second distance, the second distance being less than the first distance.

In one embodiment of the first aspect, the first and second conductors originate at an upper point of the probe.

In one embodiment of the first aspect, the capacitive level sensor probe comprises a third conductor.

In one embodiment of the first aspect, the third conductor extends along the probe for a similar distance or substantially the same distance as that for the first conductor.

In one embodiment of the first aspect, the first second and third conductors originate at an upper point of the probe sensor.

In one embodiment of the first aspect, the first and third conductors terminate at a lower point of the probe sensor.

In one embodiment of the first aspect, the second conductor terminates at a point intermediate to its point of origin and the lower point of the probe sensor.

In one embodiment of the first aspect, the first and third conductors extend for most or substantially the entire length of the probe.

In one embodiment of the first aspect, each of the conductors is elongate and substantially parallel to each other.

In one embodiment of the first aspect, each of the conductors is substantially parallel to the long axis of the probe.

In one embodiment of the first aspect, the capacitive level sensor probe is fabricated substantially as a circuit board with the conductors embodied in the form of conductive tracks formed on the circuit board.

In one embodiment of the first aspect, the first and second conductors are formed on a first side of the circuit board.

In one embodiment of the first aspect, where the probe comprises a third conductor, the third conductor is disposed on the second side of the circuit board.

In one embodiment of the first aspect, the surface area of the third conductor is (i) greater than the surface area of the first conductor and/or (ii) greater than the surface area of the second conductor and/or (iii) greater than the combined surface areas of the first and second conductors.

In a second aspect, the present invention provides a level sensor system comprising the capacitive level sensor probe of any embodiment of the first aspect and an alternating current source.

In one embodiment of the second aspect, the level sensor system comprising a first alternating current supplied across the first and third conductors, and a second alternating current applied across the second and third conductors such that a first capacitance value is readable across the first and third conductors, and a second capacitance value is readable across the second and third conductors.

In one embodiment of the second aspect, the level sensor system comprises an analogue to digital converter configured to an input an analogue capacitance value read from a pair of conductors, and output a digital value consistent with the input capacitance value.

In one embodiment of the second aspect, the level sensor system comprises a processor configured to input an analogue or digital capacitance value.

In one embodiment of the second aspect, the level sensor system comprises electronic memory in operable communication with the processor.

In one embodiment of the second aspect, the electronic memory has stored therein a relationship between a capacitance value and a flowable substance level, or a proportional flowable substance level, or a flowable substance amount, or a proportional flowable substance amount, or a flowable substance volume, or a proportional flowable substance volume, or a distance along a conductor, or a proportional distance along a conductor.

In one embodiment of the second aspect, the processor is configured to output a flowable substance level, or a proportional flowable substance level, or a flowable substance amount, or a proportional flowable substance amount, or a flowable substance volume, or a proportional flowable substance volume, or a distance along a conductor, or a proportional distance along a conductor based on an input capacitance value.

In one embodiment of the second aspect, the electronic memory comprises processor-executable instructions to execute a calibration routine with the aim of accurately and/or precisely correlating a capacitance value to a level of a flowable substance about the capacitive level sensor probe.

In one embodiment of the second aspect, the calibration routine comprises the steps of, as the level of a flowable substance rises or falls, about the capacitive level sensor probe, identifying a first detectable alteration in capacitance and identifying a second detectable alteration in capacitance.

In one embodiment of the second aspect, wherein in the calibration routine:
(i) the first detectable alteration in capacitance is identified in relation to capacitance across the first and third conductors (where present), and the second detectable alteration in capacitance is identified in relation to capacitance across the second and third conductors (where present), or
(ii) the first detectable alteration in capacitance is identified in relation to capacitance across the second and third conductors (where present), and the second detectable alteration in capacitance is identified in relation to capacitance across the first and third conductors (where present).

In one embodiment of the second aspect, in the calibration routine: the detectable alteration in capacitance is an alteration in the rate of change of capacitance, or a transition between two capacitance values, or a brief excursion from a capacitance value

In one embodiment of the second aspect, in the calibration routine: the first detectable alteration in capacitance is recognised as a first predetermined point along the length of the capacitive level sensor probe and the second detectable alteration is recognised as a second predetermined point along the length of the capacitive sensor probe.

In one embodiment of the second aspect, in the calibration routine a relationship between capacitance and the level of a flowable substance is established by reference to capacitance values for the first predetermined point along the length of the capacitive sensor probe and the second predetermined point along the length of the capacitive sensor probe.

In one embodiment of the second aspect, in the calibration routine a relationship between capacitance and the level of a flowable substance is established for 3, 4, 5, 6, 7, 8, 9, 10 or a plurality of capacitance values between the first predetermined point along the length of the capacitive sensor probe and the second predetermined point along the length of the capacitive level sensor probe.

In one embodiment of the second aspect, in the calibration routine: the relationship between capacitance and the level of a flowable substance is established by interpolation.

In one embodiment of the second aspect, the electronic memory comprises processor-executable instructions to execute a level measurement routine with the aim of accurately and/or precisely determining the level of a flowable substance about the capacitive level sensor probe.

In one embodiment of the second aspect, in the level measurement routine: a relationship between capacitance and the level of a flowable substance about the capacitive level sensor probe obtained by way of the calibration routine is utilized to determine the level of a flowable substance about the capacitive level sensor probe.

In one embodiment of the second aspect, the level sensor system comprises output means configured to output the level of a flowable substance about the capacitive level sensor probe in human-comprehensible form.

In one embodiment of the second aspect, the level sensor system comprises output means configured to output the level of a flowable substance about the capacitive level sensor probe in computer-comprehensible form.

In one embodiment of the second aspect, the processor is configured to control a component external to the system, the control being dependent on a measured level of flowable substance about the capacitive level sensor probe.

In one embodiment of the second aspect, the component external system is a valve or a pump or a heater.

In a third aspect, the present invention provides a method for calibrating a capacitive level sensor as described by reference to any of the calibration routine steps of the second aspect.

In one embodiment of the third aspect, the method is executed on the level sensor probe of any embodiment of the first aspect, or on the level sensor system of any embodiment of the second aspect.

In a fourth aspect, the present invention provides a method of measuring the level of a flowable substance, the method comprising the step of using a conductance reading form a level sensor probe of any embodiment of the first aspect, or the level sensor system of any embodiment of the second aspect. In one embodiment, the method is preceded by a method for calibration as defined in any embodiment of the third aspect.

### BRIEF DESCRIPTION OF THE DRAWINGS

FIG. 1A shows a lateral diagrammatic representation of a preferred level sensor probe of the present invention.

FIG. 1B shows a lateral diagrammatic representation of the reverse side of the level sensor probe shown in FIG. 1A.

FIG. 2 shows a lateral cross-sectional presentation of the level sensor probe of FIGS. 1A and 1B in situ within a tank containing water.

FIG. 3 is a graph showing the relationship between capacitance (y-axis) for the first and second conductors of a level sensor probe according to the present invention, and water level (y-axis) versus time (y-axis).

### DETAILED DESCRIPTION OF THE INVENTION INCLUDING PREFERRED EMBODIMENTS

Reference throughout this specification to “one embodiment” or “an embodiment” or similar wording means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and from different embodiments, as would be understood by those in the art.

In the claims below and the description herein, any one of the terms “comprising”, “comprised of” or “which comprises” is an open term that means including at least the elements/features that follow, but not excluding others. Thus, the term comprising, when used in the claims, should not be interpreted as being limitative to the means or elements or steps listed thereafter. For example, the scope of the expression a method comprising step A and step B should not be limited to methods consisting only of methods A and B. Any one of the terms “including” or “which includes” or “that includes” as used herein is also an open term that also means including at least the elements/features that follow the term, but not excluding others. Thus, “including” is synonymous with and means “comprising”.

The invention has been described with reference to certain advantages. It is not suggested or represented that each embodiment of the invention have all of the advantages described. Any particular embodiment may have only a single advantage. In some embodiments, the invention may provide no advantage and merely provide a useful alternative to the prior art.

Applicant has devised a capacitive level sensor probe that is capable of generating two signals in the course of a calibration routine: the first signal is generated when the substance under measurement crosses a first physical point on the probe, and the second signal is generated when the substance crosses a second physical point on the probe. The signals are useful in so far as they set a direct correlation between a physical point on the sensor probe and a capacitance value. For example, the first point on the probe may be near the bottom of a tank and reflect a fill level of 10% while the second point may be near the top of tank and reflect a fill level of 90%. In the calibration routine, a plurality of capacitance values are taken and utilized (by a microprocessor, for example) to generate a relationship between fill levels of between 10% and 90% and capacitance values. In a measurement situation this relationship may be used to determine a fill between the 10% and 90%.

In all capacitance level sensors, there is often a drift over time in the capacitance value for a given fill level. The corollary is that a sensor which initially reports an accurate fill level of 20% may after some time report an inaccurate value of 22%, and then later on a more inaccurate value of 25%. In the present invention such drift is automatically corrected when the tank is filled and emptied in the normal course of use given that the substance within the tank crosses the first and second physical points of the probe during draining and filling. Indeed, a probe of the present invention may be capable of self-calibrating upon first filling of the tank given that the substance will cross the first and second physical points of the sensor probe in the filling process.

Alternatively, the tank may be deliberately emptied and filled in order to force a recalibration of the sensor probe.

The present sensor probe is configured to generate identifiable signals when the level of a substance passes two physical points along its length. These signals may be generated by any means deemed suitable by the skilled person having the benefit of the present specification. In one embodiment however, the sensor comprises two capacitance-detecting circuits of having different length. The first circuit may rely on a first conductor, with the second circuit relying on a second (shorter) conductor.

The conductors may be provided by any means deemed suitable by the skilled artisan having the benefit of the present specification. The conductors may be fabricated from any material having the requite level of electrical conductivity for a particular application. Generally metals (including alloys) and metal composites (such as a conductive ink screen printed onto a vessel wall) may be used. It is also contemplated that non-metallic conductors such as graphite will have utility.

Physically, the conductors may be provided in the form of a wire, a rod, a track, a foil, a ribbon, or any other form deemed suitable by the skilled artisan having the benefit of the present specification.

As is well known in the field of capacitive sensors, it is not necessary that the sensor be configured to be exposed directly to the flowable substance under measurement. Indeed, in many situations the conductors of the sensor to be shielded from the substance to prevent electrical shorting of the conductors caused by a conductive flowable substance (such as municipal water). Alterations in capacitance will be noted due to any change in dielectric within the AC electrical field which extends well beyond the physical periphery of the conductor and into the surrounding environment.

In light of the above, it will be appreciated that one or more of the conductors may be disposed within the cavity of a vessel holding the flowable substance, or applied to an internal or external wall of a vessel, integral to the wall of a vessel, or distal to the vessel. As the skilled artisan appreciates, many of these arrangements will require the vessel to be fabricated from a non-conductive material so as to not provide any dielectric that could interfere with the flowable substance being the dielectric.

In use, the lower terminus of the first conductor is typically disposed at or toward the bottom of the tank. This lower terminus forms a first physical point on the sensor probe, and may be considered as a first calibration point. Considering the situation whether the tank is being filled with water from empty, capacitance values read from the first conductor may rise even before the water is level with the lower terminus due to the dielectric effect of water within the alternating current electric field which extends beyond the physical edge of the terminus. Capacitance values continue to rise steadily as the water approaches the lower terminus. When the water becomes level with and then rises above lower terminus, a detectable alteration in capacitance change may be noted given the strong dielectric effect of water disposed between the first conductor and its associated reference conductor. This detectable alteration can be considered a signal that water has just passed the first predetermined point along the length of the first sensor probe. In a trace of capacitance versus time, the point of transition can be easily seen in retrospect. Thus, in some embodiments of the invention, the first detectable alteration is detected historically when any alteration may be more easily detected against background fluctuations in capacitance.

In some cases, the lower terminus may be very proximal to, or even contacting, the tank floor in which case initially (when the tank is empty) the tank floor is the only dielectric about the conductor. The admission of water into the tank causes a rapid transition to a phase of increasing capacitance. In a trace of capacitance versus time this transition will be detectable given that capacitance will be stable (i.e. a flat trace reflective of a zero rate of change) for the time period before admission of water, and then transition to a positive rate of change as water begins to rise about the first conductor. In this case, the first calibration point is found by the change in capacitance cause by the admissible of water (being the dielectric). As the tank continues to fill, the water level rises about the first conductor and the capacitance increases accordingly. As the water rises toward the lower terminus of the second conductor, the capacitance value of that conductor also rises due to the dielectric proximity effects discussed above. As the water level rises past the lower terminus of the second conductor, a detectable alteration in capacitance is noted, and can be easily seen by historical reference to a graph of capacitance versus time. This detectable alteration may be considered a second calibration point.

An advantage of some embodiments of the invention is that the self-calibration embodiments will be operable over a broad range of flowable substances. Different substances have different dielectric constants such that a capacitive level sensor calibrated for one substance will not apply to the level measurement of a different substance. Thus, in the prior art a level sensor is generally calibrated for a single substance. Where there is a minor difference in the substance for example a difference in solute or solute concentration) the calibration will not be accurate. In the present invention, the detectable alterations in capacitance noted at the first and second points along the probe occur irrespective of the dielectric constant of the flowable substance. It will be appreciated that while absolute capacitance values for a given fill level will differ between substances having different dielectric constants, the first and second detectable alterations will correlate to the respective first and second physical points along the sensor probe Advantageously the present system is able to self-calibrate each time each time a tank is emptied and filled, and accordingly self-adjusts according the flowable substance that is in the tank at the time of calibration.

As discussed above, the present level sensor probe allows for correlation of two physical points along the length sensor probe with two capacitance values, this being achievable by the presence of two conductors of different lengths. It will be appreciated that one or more further conductors may be added to provide 3, 4, 5, 6, 7, 8, 9, 10 or more conductors each with different lengths and each of which will demonstrate a detectable alteration in capacitance as the level of flowable substance migrates past its terminus. For example, multiple conductors may be configured such as by positioning the terminus of each conductor at varying levels within a tank so as to correlate with a fill level of say, 0%, 10%, 20%, 30%, 40%, 50%, 60%, 70%, 80% 90% and 100%. While multiple conductor probes such as this will clearly be operable, such complication may be unnecessary.

It is proposed that a sensor probe having only two conductors with termini that span most or substantially the entire range of fill levels to be measured is capable of providing sufficient capacitance information. In some circumstances a substantially linear, or at least a near linear relationship between capacitance and fill level will be apparent, and therefore a fill level intermediate between that of the first point along the probe sensor and the second point along the probe sensor can be simply interpolated by a simple gradient equation such as y=mx+c. Rather than using algebraic means to calculate fill level, an electronic lookup table may be generated relating capacitance to fill level. A microprocessor that accepts a capacitance value as input is able to either mathematically calculate the fill level for that capacitance, or alternatively refer to an electronic lookup table to determine the fill level for that capacitance.

More commonly, the relationship between fill level and capacitance will not be linear and accordingly the use of a simple gradient analysis may not be appropriate. The present sensor probe may be configured to output conductance values in a continuous manner along the length of a conductor (or more than one conductor) such that a range of intermediate capacitance values are recorded in the course of a calibration routine. The range of intermediate capacitance values may be used to derive a non-linear mathematical relationship between the distance along the sensor probe (and therefore fill level) which is used in a measurement scenario to convert a sensed capacitance to a fill level. Such a relationship may be derived by processor means under the instruction of software means with the relationship stored in electronic memory in the course of the calibration routine for later reference in a level measurement scenario. Alternatively, a plurality of intermediate values may be stored in an electronic lookup table for later reference by a processor in determining an actual fill level.

As will be appreciated, extrapolation from a linear relationship or non-linear relationship is also achievable based on the teachings above. More reliable results would, however, be expected where interpolation is used.

As will be understood, capacitance is not directly output from a conductor, and is instead calculated thus:

C=E(KA/d)
where:
C=capacitance in picofarads (pF)
E=absolute permittivity of free space (a constant)
K=relative dielectric constant of the insulating material (i.e. the flowable substance
A=effective area of the conductors
d=distance between the conductors

In one embodiment of the invention, the sensor probe is fabricated substantially as a printed circuit board. Metallic tracks on the board form the conductors of the probe. The circuit board may also host a microprocessor and electronic memory capable of storing and executing program instructions such as a calibration routine and a level measurement routine. The microprocessor and memory allow for on-board capacitance value calculations, derivation of mathematical relationships between capacitance and fill level, storage of capacitance values (optionally in the form of lookup tables) or mathematical relationships, determination of fill level by reference to a stored mathematical relationship or a lookup table.

The circuit board may further host data communication means (wired or wireless) allowing for input or output of data to or from the microprocessor to another electrical or electronic component. For example, fill level data calculated by the microprocessor may be output to a visual display unit such as an electronic level gauge.

The data communication mean may be utilised so as to communicate fill level data to an external control system that controls the transport of a flowable substance into or out of a tank in which the present sensor probe is disposed.

The external control system may be configured interact (via the data communication means) with the present level sensor in the course of an automated calibration routine. For example, in the course of a calibration routine a tank is emptied and subsequently filled by the actuation of various pumps governed by the control system, with the level sensor processor being instructed by a processor of the external system to commence recording capacitance values and derive a mathematical relationship therefrom, or to construct a lookup table for later reference.

The data communications means may further allow user input, for example so as to input a dielectric constant for a flowable substance for use in a capacitance calculation executed by the processor.

As will be understood, the methods and systems described herein may be deployed in part or in whole through one or more processors that execute computer software, program codes, and/or instructions on a processor. A processor may be any kind of computational or processing device capable of executing program instructions, codes, binary instructions and the like. The processor may be or may include a signal processor, digital processor, embedded processor, microprocessor or any variant such as a coprocessor (math co-processor, graphic co-processor, communication co-processor and the like) and the like that may directly or indirectly facilitate execution of program code or program instructions stored thereon. In addition, the processor may enable execution of multiple programs, threads, and codes.

The threads may be executed simultaneously to enhance the performance of the processor and to facilitate simultaneous operations of the application. By way of implementation, methods, program codes, program instructions and the like described herein may be implemented in one or more thread. The thread may spawn other threads that may have assigned priorities associated with them; the processor may execute these threads based on priority or any other order based on instructions provided in the program code. The processor may include memory that stores methods, codes, instructions and programs as described herein and elsewhere.

Any processor may access a storage medium through an interface that may store methods, codes, and instructions as described herein and elsewhere. The storage medium associated with the processor for storing methods, programs, codes, program instructions or other type of instructions capable of being executed by the computing or processing device may include but may not be limited to one or more of memory, disk, flash drive, RAM, ROM, cache and the like.

The computer software, program codes, and/or instructions may be stored and/or accessed on computer readable media that may include: computer components, devices, and recording media that retain digital data used for computing for some interval of time; semiconductor storage known as random access memory (RAM); mass storage typically for more permanent storage, such as optical discs, forms of magnetic storage like hard disks, tapes, drums, cards and other types; processor registers, cache memory, volatile memory, non-volatile memory; optical storage such as CD, DVD; removable media such as flash memory (e.g. USB sticks or keys), floppy disks, magnetic tape, paper tape, punch cards, standalone RAM disks. Zip drives, removable mass storage, off-line, and the like; other computer memory such as dynamic memory, static memory, read/write storage, mutable storage, read only, random access, sequential access, location addressable, file addressable, content addressable, network attached storage, storage area network, bar codes, magnetic ink, and the like.

The methods and systems described herein may transform physical and/or or intangible items from one state to another. The methods and systems described herein may also transform data representing physical and/or intangible items from one state to another.

The elements described and depicted herein, including in flow charts and block diagrams throughout the figures, imply logical boundaries between the elements. However, according to software or hardware engineering practices, the depicted elements and the functions thereof may be implemented on computers through computer executable media having a processor capable of executing program instructions stored thereon as a monolithic software structure, as standalone software modules, or as modules that employ external routines, code, services, and so forth, or any combination of these, and all such implementations may be within the scope of the present disclosure.

Furthermore, the elements depicted in any flow chart or block diagrams or any other logical component may be implemented on a machine capable of executing program instructions. Thus, while the foregoing drawings and descriptions set forth functional aspects of the disclosed systems, no particular arrangement of software for implementing these functional aspects should be inferred from these descriptions unless explicitly stated or otherwise clear from the context. Similarly, it will be appreciated that the various steps identified and described above may be varied, and that the order of steps may be adapted to particular applications of the techniques disclosed herein. All such variations and modifications are intended to fall within the scope of this disclosure. As such, the depiction and/or description of an order for various steps should not be understood to require a particular order of execution for those steps, unless required by a particular application, or explicitly stated or otherwise clear from the context.

The methods and/or processes described above, and steps thereof, may be realized in hardware, software or any combination of hardware and software suitable for a particular application. The hardware may include a general purpose computer and/or dedicated computing device or specific computing device or particular aspect or component of a specific computing device. The processes may be realized in one or more microprocessors, microcontrollers, embedded microcontrollers, programmable digital signal processors or other programmable device, along with internal and/or external memory. The processes may also, or instead, be embodied in an application specific integrated circuit, a programmable gate array, programmable array logic, or any other device or combination of devices that may be configured to process electronic signals. It will further be appreciated that one or more of the processes may be realized as a computer executable code capable of being executed on a computer readable medium.

The Application software may be created using a structured programming language such as C, an object oriented programming language such as C++, or any other high-level or low-level programming language (including assembly languages, hardware description languages, and database programming languages and technologies) that may be stored, compiled or interpreted to run on one of the above devices, as well as heterogeneous combinations of processors, processor architectures, or combinations of different hardware and software, or any other machine capable of executing program instructions.

Thus, in one aspect, each method described above and combinations thereof may be embodied in computer executable code that, when executing on one or more computing devices, performs the steps thereof. In another aspect, the methods may be embodied in systems that perform the steps thereof, and may be distributed across devices in a number of ways, or all of the functionality may be integrated into a dedicated, standalone device or other hardware. In another aspect, the means for performing the steps associated with the processes described above may include any of the hardware and/or software described above. All such permutations and combinations are intended to fall within the scope of the present disclosure.

The invention may be embodied in program instruction set executable on one or more computers. Such instructions sets may include any one or more of the following instruction types:

Data handling and memory operations, which may include an instruction to set a register to a fixed constant value, or copy data from a memory location to a register, or vice-versa, to store the contents of a register, result of a computation, or to retrieve stored data to perform a computation on it later, or to read and write data from hardware devices.

Arithmetic and logic operations, which may include an instruction to add, subtract, multiply, or divide the values of two registers, placing the result in a register, possibly setting one or more condition codes in a status register, to perform bitwise operations, e.g., taking the conjunction and disjunction of corresponding bits in a pair of registers, taking the negation of each bit in a register, or to compare two values in registers (for example, to determine if one is less, or if they are equal).

Control flow operations, which may include an instruction to branch to another location in the program and execute instructions there, conditionally branch to another location if a certain condition holds, indirectly branch to another location, or call another block of code, while saving the location of the next instruction as a point to return to.

Coprocessor instructions, which may include an instruction to load/store data to and from a coprocessor, or exchanging with CPU registers, or perform coprocessor operations.

A processor of a computer of the present system may include “complex” instructions in their instruction set. A single “complex” instruction does something that may take many instructions on other computers. Such instructions are typified by instructions that take multiple steps, control multiple functional units, or otherwise appear on a larger scale than the bulk of simple instructions implemented by the given processor. Some examples of “complex” instructions include: saving many registers on the stack at once, moving large blocks of memory, complicated integer and floating-point arithmetic (sine, cosine, square root, etc.), SIMD instructions, a single instruction performing an operation on many values in parallel, performing an atomic test-and-set instruction or other read-modify-write atomic instruction, and instructions that perform ALU operations with an operand from memory rather than a register.

An instruction may be defined according to its parts. According to more traditional architectures, an instruction includes an opcode that specifies the operation to perform, such as add contents of memory to register—and zero or more operand specifiers, which may specify registers, memory locations, or literal data. The operand specifiers may have addressing modes determining their meaning or may be in fixed fields. In very long instruction word (VLIW) architectures, which include many microcode architectures, multiple simultaneous opcodes and operands are specified in a single instruction.

Some types of instruction sets do not have an opcode field (such as Transport Triggered Architectures (TTA) or the Forth virtual machine), only operand(s). Other unusual “0-operand” instruction sets lack any operand specifier fields, such as some stack machines including NOSC.

Conditional instructions often have a predicate field—several bits that encode the specific condition to cause the operation to be performed rather than not performed. For example, a conditional branch instruction will be executed, and the branch taken, if the condition is true, so that execution proceeds to a different part of the program, and not executed, and the branch not taken, if the condition is false, so that execution continues sequentially. Some instruction sets also have conditional moves, so that the move will be executed, and the data stored in the target location, if the condition is true, and not executed, and the target location not modified, if the condition is false. Similarly, IBM z/Architecture has a conditional store. Some instruction sets include a predicate field in every instruction; this is called branch predication.

The instructions constituting a program are rarely specified using their internal, numeric form (machine code); they may be specified using an assembly language or, more typically, may be generated from programming languages by compilers.

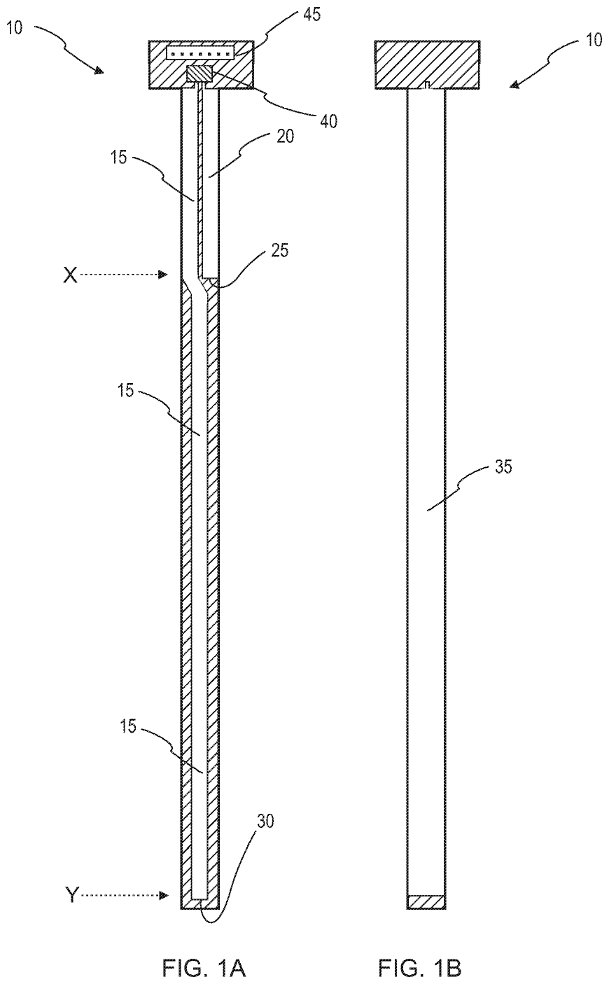

Turning now to FIG. 1 there is shown a highly preferred level sensor probe (10) of the present invention fabricated in the form of a printed circuit board. FIG. 1A shows a first side of the probe (10). FIG. 1B shows the reverse side of that shown in FIG. 1A.

Considering firstly FIG. 1A, the hatched surface 10 denotes the unprinted circuit board surface, which is of course non-conductive. By an additive method well known to the skilled artisan, conductive copper tracks were printed onto the surface (10) so as to provide a first elongate conductor (15), and a second elongate conductor (20). The first elongate conductor (15) has a terminus (25). The second elongate conductor 20 has a terminus (30). The first (15) and (second) conductors are electrically isolated from each other for their entire lengths.

On the reverse side (as shown in FIG. 1B) is a third conductive copper track forming a third conductor (35) printed thereon. The third conductor (35) is electrically isolated from both the first (15) and second (20) conductors. The third conductor (35) forms a reference electrode to which the first (15) and second (20) electrodes are individually paired. Thus, dielectric (for example, water under measurement) disposed between the third conductor (35) and the first conductor (15) may be used to provide a first capacitance value, and dielectric disposed between the third conductor (35) and the second conductor (30) may provide a second capacitance value.

The conductors (15), (20) and (35) are electrically isolated from the environment by a polymer sheath (not shown) to prevent shorting between conductors (15), (20), (35) when immersed in a conductive liquid.

Turning back to FIG. 1A, the first (15) and second (20) conductors are each connected to a pin of an integrated circuit (40) mounted on the circuit board. In this preferred embodiment, the integrated circuit is FDC1004 (Texas Instruments™) which comprises a capacitance to digital converter, configuration registers, data registers, offset/gain functions and I²C connectivity for connection to an external processor that may be used for capacitance data analysis or storage.

Connectivity to an external processor is made by way of connector (45) which in this preferred embodiment is a Molex™ 7-way PicoBlade connector.

As will be noted from FIG. 1A, the first conductor (15) extends downwardly for almost the entire length of the sensor probe (10). The terminus (30) of the first conductor (15) therefore sits very low in a tank to which the level sensor (10) is fitted. The terminus (30) therefore sets a level at a first point (marked “Y” in the drawing) in the tank.

In a calibration routine, the tank may be initially empty, and in which case the capacitance provided by the first conductor (15) is at a minimum. As the tank fills, the level of liquid passes the level “Y” thereby causing a detectable alteration in the capacitance read from the first conductor (15). At this point, a correlation may be made between a known fill level (i.e. point “Y”, which may be a 10% fill level) and a capacitance value as read from the first conductor.

The level of the liquid continues to rise at a steady rate, and the capacitance values read from the first conductor (15) keep rising.

The capacitance values read from the second conductor (20) remain at a minimum until the liquid approaches the terminus (25) of the second conductor (20) at which time proximity effects of the liquid cause the capacitance of the second conductor (20) to start rising. As the level of the liquid passes the point marked “X” in the drawings there is noted a detectable alteration in capacitance read from the second conductor (20). At this point, a correlation may be made between a known fill level (i.e. point “X”, which may be a 90% fill level) and a capacitance value as read from the second conductor (35). In addition or alternatively, a correlation may be made between a known fill level (i.e. point “X”, which may be a 90% fill level) and a capacitance value as read from the first conductor (15).

The capacitance values read from the first conductor (15) as the liquid level rose between points “Y” and “X” were retained in electronic memory and are utilized by an external processor (not shown) to derive a mathematical relationship between capacitance value and fill level. After calibration and when the level sensor 10 is in level measuring mode these values are used to determine intermediate fill levels. The fill level may be determined by reference to the known fill level at point “Y” or the known fill level at point “X” or by reference to both.

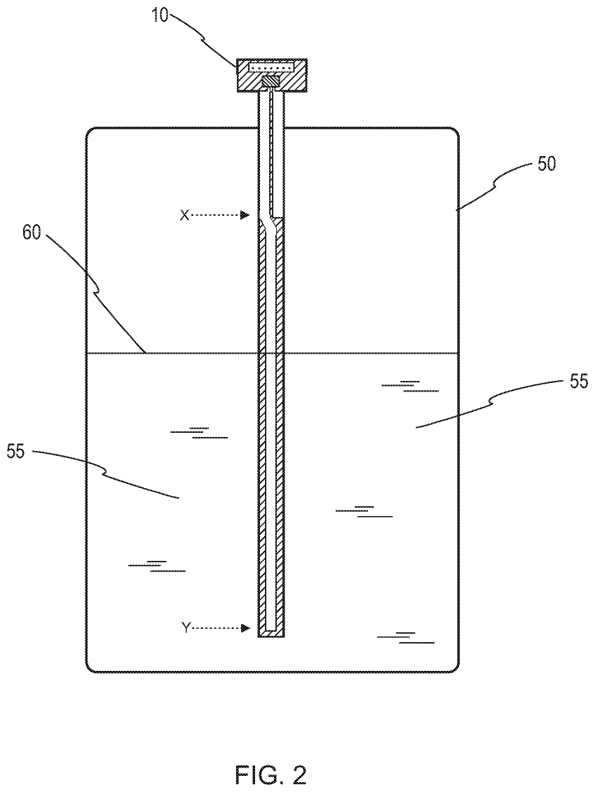

Reference is made to FIG. 2 which shows a level sensor probe (10) of the present invention as fitted to a tank (50) containing water (55) at a level (60) intermediate to that of point “X” and point “Y”.

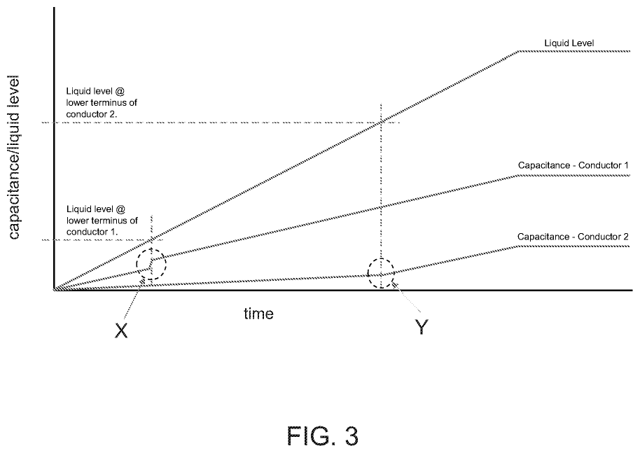

Turning now to FIG. 3, there is shown an idealized graph derived from raw capacitance data using water as the dielectric, and a probe constructed in general accordance with that shown FIG. 1 and disposed in a tank generally as shown in FIG. 2. The detectable alterations in capacitance are marked “X” and “Y” on the graph. As will be appreciated, the gradients of the traces, the nature of the detectable alterations, and the appearance of other features on the traces will depend on factors such as the material and construction of the probe sensor, the dielectric, and the magnitude and frequency of the alternating current, amongst others.

Although described mainly be reference to the measurement of water level within a tank, the present invention has applicability to other circumstances. For example, the invention may be operable in determining the level of fuel within a vehicle tank, the level of a beverage in an industrial process tank, the level of water in an open reservoir, the level of grain in a silo, or determining the level of flour in a vat. In preferred embodiments, however, the present level sensor is used in small scale electrical appliances such as the water tanks present in on-bench or under-bench water heaters and coolers used to dispense beverages for human consumption.

While the invention has been disclosed in connection with the preferred embodiments shown and described in detail, various modifications and improvements thereon will become readily apparent to those skilled in the art.

Accordingly, the spirit and scope of the present invention is not to be limited by the foregoing examples, but is to be understood in the broadest sense allowable by law.

1. A capacitive level sensor probe being generally elongate and comprising conductors configured such that, in use, as the level of a flowable substance crosses a first predetermined point along the length of the sensor a first detectable alteration in capacitance is generated, and as the level of a flowable substance crosses a second predetermined point along the length of the sensor a second detectable alteration in capacitance is generated.

2. The capacitive level sensor probe of claim 1, wherein the detectable alteration in capacitance is an alteration in the rate of change of capacitance, or a transition between two capacitance values, or a brief excursion from a capacitance value.

3. The capacitive level sensor probe of claim 1 comprising a first conductor and a second conductor, the first conductor extending along the probe for a first distance, the second conductor extending along the probe for a second distance, the second distance being less than the first distance.

4. The capacitive level sensor probe of claim 3, wherein the first and second conductors originate at an upper point of the probe.

5. The capacitive level sensor probe of claim 1 comprising a third conductor.

6. The capacitive level sensor probe of claim 5, wherein the third conductor extends along the probe for a similar distance or substantially the same distance as that for the first conductor.

7. The capacitive level sensor probe of claim 6, wherein the first second and third conductors originate at an upper point of the probe sensor.

8. The capacitive level sensor probe of claim 6, wherein
the first and third conductors terminate at a lower point of the probe sensor.

9. The capacitive level sensor probe of claim 8, wherein the second conductor terminates at a point intermediate to its point of origin and the lower point of the probe sensor.

10. The capacitive level sensor probe of claim 1, wherein the first and third conductors extend for most or substantially the entire length of the probe.

11. A level sensor system comprising
a capacitive level sensor probe being generally elongate and comprising conductors configured such that, in use, as the level of a flowable substance crosses a first predetermined point along the length of the sensor a first detectable alteration in capacitance is generated, and as the level of a flowable substance crosses a second predetermined point along the length of the sensor a second detectable alteration in capacitance is generated, and
an alternating current source.

12. The level sensor system of claim 11, wherein the capacitive level sensor probe comprises a first conductor, a second conductor and a third conductor, the first conductor extending along the probe for a first distance, the second conductor extending along the probe for a second distance, the second distance being less than the first distance, the third conductor extending along the probe for a similar distance or substantially the same distance as that for the first conductor, any the system comprises a first alternating current supplied across the first and third conductors, and a second alternating current applied across the second and third conductors such that a first capacitance value is readable across the first and third conductors, and a second capacitance value is readable across the second and third conductors.

13. The level sensor system of claim 12, comprising an analogue to digital converter configured to an input an analogue capacitance value read from a pair of conductors, and output a digital value consistent with the input capacitance value.

14. The level sensor system of claim 11 comprising a processor configured to input an analogue or digital capacitance value and electronic memory in operable communication with the processor.

15. The level sensor system of claim 14 wherein the electronic memory has stored therein a relationship between a capacitance value and a flowable substance level, or a proportional flowable substance level, or a flowable substance amount, or a proportional flowable substance amount, or a flowable substance volume, or a proportional flowable substance volume, or a distance along a conductor, or a proportional distance along a conductor.

16. The level sensor system of claim 14, wherein the electronic memory comprises processor-executable instructions to execute a calibration routine with the aim of accurately and/or precisely correlating a capacitance value to a level of a flowable substance about the capacitive level sensor probe.

17. The level sensor system of claim 16, wherein the calibration routine comprises the steps of, as the level of a flowable substance rises or falls, about the capacitive level sensor probe, identifying a first detectable alteration in capacitance and identifying a second detectable alteration in capacitance.

18. The level sensor system of claim 17, wherein in the calibration routine:
(i) the first detectable alteration in capacitance is identified in relation to capacitance across the first and third conductors (where present), and the second detectable alteration in capacitance is identified in relation to capacitance across the second and third conductors (where present), or
(ii) the first detectable alteration in capacitance is identified in relation to capacitance across the second and third conductors (where present), and the second detectable alteration in capacitance is identified in relation to capacitance across the first and third conductors (where present).

19. The level sensor system of claim 17, wherein in the calibration routine: the first detectable alteration in capacitance is recognised as a first predetermined point along the length of the capacitive level sensor probe and the second detectable alteration is recognised as a second predetermined point along the length of the capacitive sensor probe.

20. The level sensor system of claim 11, wherein in the calibration routine a relationship between capacitance and the level of a flowable substance is established by reference to capacitance values for the first predetermined point along the length of the capacitive sensor probe and the second predetermined point along the length of the capacitive sensor probe, and wherein the electronic memory comprises processor-executable instructions to execute a level measurement routine with the aim of accurately and/or precisely determining the level of a flowable substance about the capacitive level sensor probe, and wherein in the level measurement routine: a relationship between capacitance and the level of a flowable substance about the capacitive level sensor probe obtained by way of the calibration routine is utilized to determine the level of a flowable substance about the capacitive level sensor probe.

21. (canceled)
